(19) United States
(12) Patent Application Publication
(10) Pub. No.: US 2010/0102431 A1
(43) Pub. Date: Apr. 29, 2010

(54) POWER MODULE AND INVERTER FOR VEHICLES

(75) Inventor: Takashi Atsumi, Okazaki-shi (JP)

Correspondence Address: SUGHRUE MION, PLLC, 2100 PENNSYLVANIA AVENUE, N.W., SUITE 800, WASHINGTON, DC, 20037, US

(73) Assignee: TOYOTA JIDOSHA KABUSHIKI KAISHA, Toyota-shi, Aichi (JP)

(21) Appl. No.: 12/532,584

(22) PCT Filed: Mar. 21, 2008
(86) PCT No.: PCT/JP2008/055988

§ 371 Date: Sep. 22, 2009

(30) Foreign Application Priority Data
Mar. 22, 2007 (JP) 2007-074811

(51) Int. Cl. H01L 23/488; H01L 23/31; H01L 25/07; H01L 25/18

(52) U.S. Cl. 257/690; 257/E25.014; 257/701; 257/E23.023; 257/E23.129

(57) ABSTRACT

According to the present invention, a power module in which the thermal stress between a semiconductor chip and a substrate is relaxed by liquefaction of a solder layer, by which the semiconductor chip is positioned on the substrate, such that generation of cracks between the semiconductor chip and the substrate can be prevented and bonding strength is ensured is provided. Further, the following is provided: a power module 1 comprises a semiconductor chip 2 and a substrate 3 on which the semiconductor chip 2 is positioned The power module further comprises a solder layer 4 provided between the semiconductor chip 2 and the substrate 3, the solder layer 4 liquefying due to heat generated by the semiconductor chip 2 and a resin material 5 that connects the semiconductor chip 2 and the substrate 3, the resin material 5 deforming to follow the thermal expansion difference between the semiconductor chip 2 and the substrate 3 that is generated upon the heat generation. The melting point of the resin material 5 is higher than the melting point of the solder layer 4.

### TECHNICAL FIELD

The present invention relates to a power module comprising a semiconductor device used for the supply of power to hybrid vehicles and the like. In particular, the present invention relates to a power module in which crack generation in a bonding material used between a semiconductor chip serving as a heat-generating element and a substrate upon which the semiconductor chip is positioned can be prevented, and an inverter for vehicles provided with the power module.

### BACKGROUND ART

As shown in FIG. 3, a power module 21, which is a conventional power module used for vehicles as described above, is composed of at least an insulating substrate 23 on which a semiconductor chip 22 is positioned in an insulated state and a heat-dissipating element 27 which dissipates heat generated by the semiconductor chip 22. In addition, the semiconductor chip 22 is fixed to a conductor 24 attached to the insulating substrate 23 via a solid metal bond with the use of a high-melting point bonding material 25. A conductor 26 attached to the insulating substrate 23 and the heat-dissipating element 27 are fixed to each other with a low-melting point bonding material 28 such as a solder.

In addition, one example of such a semiconductor device is a hybrid integrated circuit disclosed in Patent Document 1. The hybrid integrated circuit has a substrate on which an electrically conductive path is formed in a desired shape. In addition, a chip condenser and/or chip resistance are connected via a solder layer to a fixation pad provided at a desired location on the electrically conductive path. The solder layer is composed of at least two solder materials that are different in terms of the liquidus line temperature. Further, regarding the two solder materials used for the mixed integrated circuit, a first solder material has a liquidus line temperature of approximately 125° C. to 236° C., and a second solder material has a liquidus line temperature of 183° C. to 300° C. In addition, in the solder layer, the second solder material in a particle form is mixed in with the first solder material.

Patent Document 1: JP Patent Publication (Kokai) No. 6-37438 A (1994)

### DISCLOSURE OF THE INVENTION

As an aside, in the above power module shown in FIG. 3, the semiconductor chip generates heat upon operation. The linear expansion coefficient for semiconductor chips is generally approximately 3 ppm. The linear expansion coefficient for insulating substrates is generally approximately 4 to 5 ppm. In addition, there is a significant difference between the displacement “a” obtained as a result of thermal expansion of a semiconductor chip and the displacement “b” obtained as a result of thermal expansion of an insulating substrate at high temperatures. Accordingly, due to the displacement difference (thermal expansion difference) obtained as a result of thermal expansion, thermal stress is generated at the boundary between the semiconductor chip and the insulating substrate. In the case of fixation with a solid metal bond, stress is concentrated, resulting in crack generation. For such reason, it is necessary to use an insulating substrate having a low linear expansion coefficient (close to the linear expansion coefficient for semiconductor chips) such as a substrate made of aluminium nitride, silicon nitride, or the like. In addition, it is necessary to use a particular high-melting point bonding material in order to ensure the bonding strength between a semiconductor chip and an insulating substrate. Since the aforementioned insulating substrate and the high-melting point bonding material are expensive, the use of such substrate or material is an obstacle for cost reduction of power modules.

In addition, in the hybrid integrated circuit disclosed in Patent Document 1, a first solder material for a solder layer that is mainly used for connection of a chip condenser and/or a chip resistance forms a liquid phase. This might cause lack of binding strength, which is problematic. In particular, when the aforementioned hybrid integrated circuit or semiconductor device is used for a power module for the supply of power to hybrid vehicles and the like, the conduction state might become unstable due to vibration or the like generated by vehicles in motion.

The present invention has been made in view of the above problems. It is an object of the present invention to provide a power module in which the thermal stress between a semiconductor chip and a substrate is relaxed by liquefaction of a solder layer, by which the semiconductor chip is positioned on the substrate, at high temperatures such that generation of cracks between the semiconductor chip and the substrate can be prevented and bonding strength is ensured and to provide an inverter for vehicles provided with the same. It is another object of the present invention to provide a power module and an inverter for vehicles that can realize cost reduction.

In order to achieve the above objects, the power module of the present invention comprises a semiconductor chip and a substrate on which the semiconductor chip is positioned. The power module further comprises a solder layer provided between the semiconductor chip and the substrate. The solder layer liquefies due to heat generated by the semiconductor chip. The power module further comprises a resin material that connects the semiconductor chip and the substrate. The resin material deforms to follow the thermal expansion difference between the semiconductor chip and the substrate that is generated upon the heat generation. The melting point of the resin material is higher than the melting point of the solder layer.

In the power module of the present invention configured as above, the semiconductor chip generates heat by supplying the semiconductor chip with the electric current. As a result of heat generation, the bonding strength between the substrate and the semiconductor chip positioned thereon via the solder layer decreases due to liquefaction of the solder layer. However, since the semiconductor chip and the substrate are connected with each other via the resin material, the bonding strength can be ensured. In addition, the semiconductor chip is positioned on the substrate with the use of the solder layer in a liquid state. Therefore, the reign material can deform to follow a thermal expansion difference between the semiconductor chip and the substrate, and the liquefaction of the solder layer prevents from crack generation and the like. Further, even if the solder layer becomes molten, the resin material does not become molten. Therefore, the state of the semiconductor chip positioned on the substrate is stabilized. In addition to that, the use of a usual low-melting point solder realizes cost reduction.

In addition, in a preferred specific embodiment of the power module of the present invention, the resin material surrounds at least the circumference of the semiconductor chip. In the power module configured as above, the resin material surrounds the circumference of the semiconductor chip such that leakage of the solder layer in a liquid state can be prevented, which results in secure fixation of the semiconductor chip.

Further, in another preferred specific embodiment of the power module of the present invention, the resin material has a Young's modulus of 1 to 20 GPa and the resin material has a heatproof temperature of 160° C. to 240° C. When the Young's modulus and the heatproof temperature are determined to fall within the above ranges, it becomes possible to connect the semiconductor chip to the substrate and fix it thereon so as to follow the thermal expansion difference between the semiconductor chip and the substrate.

In addition, preferably, the resin material is at least one resin selected from the group comprising polyimide resin, epoxy resin, urethane resin, and silicone resin. Such a resin is excellent in thermal resistance. Therefore, when the resin material is prepared with the use of such a resin, it becomes possible to connect the semiconductor chip to the substrate and fix it thereon such that the resin material deforms to follow the thermal expansion difference between the semiconductor chip and the substrate.

Furthermore, preferably, in the case of the power module of the present invention, the resin material has layers comprising plural types of the above resins. According to the present invention, it becomes possible to form layers comprising different resins along with the thickness direction of the resin material. Therefore, a resin material can be formed by selecting resins depending on use environments along with the thickness direction. For instance, it is possible to form a resin layer that comes into contact with a solder layer with a resin that can readily follow a thermal expansion difference and then to form a resin layer with high rigidity in a manner such that it covers the above layer. More specifically, it is preferable to form a resin layer that comes into contact with a solder layer with a silicone resin and then to form an epoxy resin layer in a manner such that it covers the silicone resin layer.

The inverter for vehicles of the present invention is provided with any one of the power modules described above. In an inverter for vehicles configured in the manner described above, when a semiconductor chip generates heat, the solder layer between a semiconductor chip and a substrate on which the semiconductor is positioned liquefies such that thermal stress is relaxed and crack generation is prevented. In addition, binding between the semiconductor chip and the substrate is ensured with the resin material. The solder layer in a liquid state is surrounded by the resin material. Therefore, leakage of the solder material in a liquid state is prevented.

In the power module of the present invention and an inverter for vehicles provided with the power module, a solder layer used for fixation of a semiconductor chip liquefies during operation at high temperatures, resulting in relaxation of thermal stress. Thus, crack generation between a semiconductor chip and a substrate can be prevented. In addition, a resin material prevents leakage of a solder layer in a liquid state. The bonding strength of the semiconductor chip can be ensured.

This description includes part or all of the contents as disclosed in the description and/or drawings of Japanese Patent Application No. 2007-74811, which is a priority document of the present application.

### BRIEF DESCRIPTION OF THE DRAWINGS

FIG. 1 shows a cross section of a power module in one embodiment of the present invention.

FIG. 2 shows a configuration diagram of an inverter for vehicles provided with the power module shown in FIG. 1 in one embodiment of the present invention.

FIG. 3 shows a cross section of a conventional power module.

In the above drawings, numerical references 1, 2, 3, 4, 5, and 10 denote a power module, a semiconductor chip, an insulating substrate (substrate), a solder layer, a resin material, and an inverter for vehicles, respectively.

### BEST MODE FOR CARRYING OUT THE INVENTION

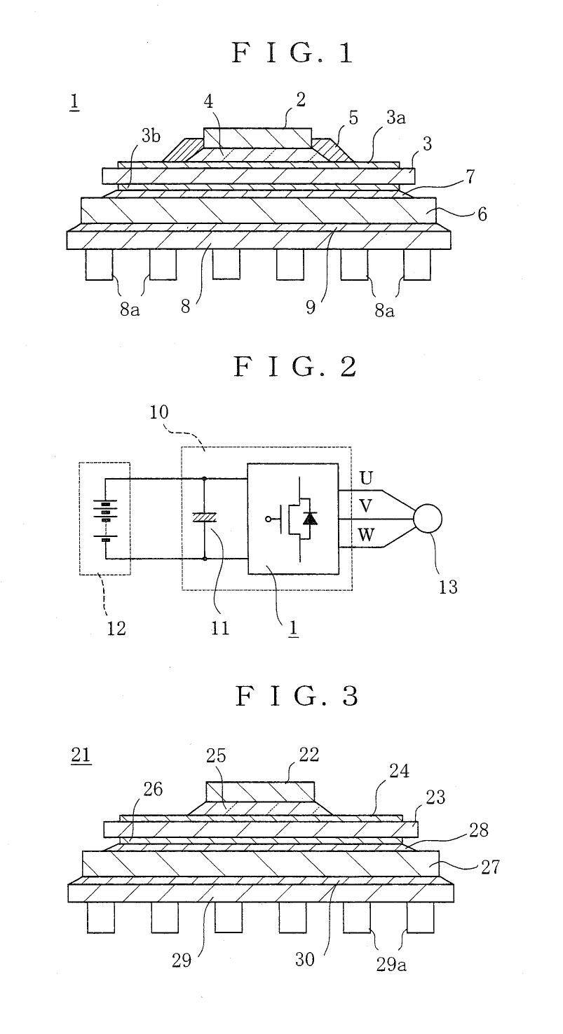

Hereinafter, the power module used in one embodiment of the present invention is described in detail with reference to the drawings. FIG. 1 shows a cross section of a power module in this embodiment of the present invention.

In FIG. 1, a power module 1 comprises a semiconductor chip 2 and an insulating substrate 3 on which the semiconductor chip is positioned. The semiconductor chip 2 is fixed via a solder layer 4 on a conductor 3a having metallic foil, a conductive pattern, and the like formed on the upper face of the insulating substrate 3. The insulating substrate 3 has a function of insulating the flow of the electric current from the semiconductor chip 2 and a function of transmitting heat generated from the semiconductor chip 2. For instance, the insulating substrate 3 is formed with insulating materials such as ceramics. A conductor 3b is also formed on the lower face thereof.

The solder layer 4 that connects the semiconductor chip 2 and the insulating substrate 3 is configured in a manner such that it liquefies due to heat generated upon operation of the semiconductor chip 2, which results in relaxation of thermal stress generated therebetween. That is, the solder layer 4 liquefies (or becomes in the solid-liquid coexisting state in some cases) as a result of heat generated during operation of the semiconductor chip 2. Therefore, the power module 1 in this embodiment is further provided with a resin material 5 that connects a semiconductor chip 2 and an insulating substrate 3 because the bonding strength between the semiconductor chip 2 and the insulating substrate 3 via a solder layer 4 becomes weak at high temperatures.

The resin material 5 is formed with, for example, a flexible resin. The resin material (resin member) connects the semiconductor chip 2 and the insulating substrate 3. The resin material is able to deform to follow the thermal expansion difference between the semiconductor chip 2 and the insulating substrate 3 at high temperatures. In addition, the resin material 5 is structured to surround the circumference of the semiconductor chip 2. Specifically, the resin material 5 is formed to cover the circumference of the solder layer 4 and couples the upper face of the insulating substrate 3 with the side surface of the semiconductor chip 2. In addition, the melting point of the resin material 5 is set at a higher point than the melting point of the solder layer 4 in a manner such that the resin material 5 does not become molten upon of liquefaction of the solder layer 4.

Specifically, in consideration of the heat generation temperature of a general semiconductor chip 2, it is desirable that a solder layer material have a thermal conductivity of 60 to 100 W/mK and a melting point temperature of 90° C. to 190° C. When such a material has a thermal conductivity of less than 60 W/mK, heat generated from a semiconductor cannot be efficiently transmitted. When such a material has a thermal conductivity of more than 100 W/mK, material cost increases. In addition, when the melting point is below a temperature of 90° C., the bonding strength between the semiconductor chip 2 and the insulating substrate 3 becomes insufficient at temperatures at which thermal stress is low. When the melting point exceeds 190° C., liquefaction is unlikely to take place due to heat generated by the semiconductor chip 2. In addition, general industrially available solder materials correspond to solder materials that satisfy requirements of the above temperature regions of the thermal conductivity and the melting point. Such materials have general-purpose properties and they are inexpensive. Such solder materials may or may not contain lead. In view of environmental resistance, lead-free solders are preferable. For example, solders comprising tin or tin alloys are more preferable.

Further, the layer thickness of the solder layer 4 is preferably 0.1 mm to 1.0 mm. When the thickness of the solder layer is less than 0.1 mm, the bonding strength provided by the solder layer becomes insufficient at ordinary temperatures. In such case, it is difficult to form a resin material that can deform to follow the thermal expansion difference between the semiconductor chip and the substrate. In addition, even if the layer thickness of the solder layer is more than 1.0 mm, the bonding strength and the like cannot be further improved at ordinary temperatures. In addition, the amount of the solder material that liquefies due to heat generated by the semiconductor chip increases, which is not preferable.

The resin material 5 that can be used is formed with at least one resin selected from the group comprising polyimide resin, epoxy resin, urethane resin, and silicone resin. It has a heatproof temperature of 160° C. to 240° C. In consideration of the heat generation temperature of a general semiconductor chip 2, when the heatproof temperature is less than 160° C., the resin material might become molten with the solder layer 4. In addition, it is difficult to expect to obtain a semiconductor chip that can generate heat over 240° C. In such case, material cost increases. Further, the resin material 5 that can be used has a Young's modulus (longitudinal elastic modulus) of 1 to 20 GPa. When such Young's modulus is less than 1 GPa, the bonding strength between a semiconductor chip 2 and an insulating substrate 3 via an appropriate resin becomes insufficient. When the Young's modulus exceeds 20 GPa, the thermal expansion difference cannot be absorbed. Further, in order to improve heat dissipation performance of the resin, insulating particles comprising ceramics such as Si, SiC, and alumina may be mixed therein.

The above resin material 5 is molded by placing a molding frame (not shown) having a shape that allows the resin material to cover the upper surface of the insulating substrate 3 and the side surface of a semiconductor chip 2 on the insulating substrate 3, injecting the flexible resin material described above into the molding frame, and removing the molding frame. Alternatively, the resin material 5 can be molded by injecting a flexible resin via a nozzle into a corner portion formed by the insulating substrate 3 and the semiconductor chip 2 that are in contact with each other. In this embodiment, a power line and a signal line (not shown) are connected to the upper surface of the semiconductor chip 2 such that the side surface portion of the semiconductor chip 2 is connected to the insulating substrate 3 via the resin material 5. However, if connection between a power line and a signal line can be ensured, the semiconductor chip may be connected to the substrate by covering the upper portion of the semiconductor chip with the resin material.

A radiator plate 6 is fixed to the lower portion of the insulating substrate 3 by soldering. Specifically, a solder layer 7 is formed between a conductor 3b located in the lower portion of the insulating substrate 3 and the radiator plate 6 for fixation. Accordingly, in the above configuration, heat generated from the semiconductor chip 2 is conducted through the solder layer 4 to the insulating substrate 3 and further conducted through the solder layer 7 to the heat-dissipating element 6, resulting in heat dissipation in, for example, the atmosphere or cooling water.

Operation in the power module 1 with the above configuration in this embodiment is described below. When the electric current is supplied to the semiconductor chip 2 constituting the power module 1 and thus rated working conditions are provided, the semiconductor chip 2 generates heat and the generated heat is conducted through the solder layer 4 to the insulating substrate 3. Heat generation from the semiconductor chip 2 causes thermal expansion of the semiconductor chip 2 at a thermal expansion rate of approximately 3 ppm in accordance with the Young's modulus (linear expansion coefficient). For instance, the semiconductor chip 2 generates heat at a temperature of more than 150° C. upon rated output, causing liquefaction of the solder layer.

Heat generated from the semiconductor chip 2 is conducted through the solder layer 4 to the insulating substrate 3. This results in thermal expansion of the insulating substrate 3 at a thermal expansion rate of approximately 4 to 5 ppm in accordance with the linear expansion coefficient. As described above, there is a displacement difference between thermal expansion of the semiconductor chip 2 and thermal expansion of the insulating substrate 3 (difference between arrows “a” and “b” shown in FIG. 3). However, in this embodiment, the solder layer 4 liquefies or becomes in a solid-liquid coexisting state. Therefore, there is no thermal stress generated between the semiconductor chip 2 and the insulating substrate 3, resulting in no crack generation or the like.

Further, since the semiconductor chip 2 and the insulating substrate 3 are connected with each other via the resin material 5, the resin material 5 is able to deform to follow the thermal expansion difference between the semiconductor chip 2 and the insulating substrate 3. As a result, the bonding strength of the solder layer 4 decreases as a result of liquefaction (or such solder layer becoming in a solid-liquid coexisting state in some cases). However, even if the solder layer 4 becomes molten, the resin material 5 does not become molten. The semiconductor chip 2 and the insulating substrate 3 are securely connected with each other via the resin material 5. Therefore, the semiconductor chip 2 is stably positioned on the insulating substrate 3 so as not to be detached therefrom.

As described above, the resin material of the power module 1 in this embodiment can deform to follow a thermal expansion difference between the semiconductor chip 2 and the insulating substrate 3 at high temperatures. This results in the stably positioned state of the semiconductor chip 2 and good conduction of generated heat. As a result, heat generated from the semiconductor 2 can be efficiently dissipated.

Next, an inverter for vehicles provided with the power module of the present invention is described in one embodiment with reference to FIG. 2. In FIG. 2, the inverter for vehicles 10 in this embodiment is used for hybrid vehicles each comprising an engine and a motor, electric vehicles, and the like. Such inverter is a power conversion apparatus that converts direct current into alternating current and supplies power to an alternating current loading apparatus such as an induction motor. In the minimum configuration, the inverter for vehicles 10 is provided with the power module 1 and the electrolytic capacitor 11 in the above embodiment. In addition, DC power source 12 such as a battery is connected to the inverter for vehicles 10. The UVW three-phase alternating current outputted from the inverter for vehicles 10 is supplied to, for example, an induction motor 13 for driving the induction motor. Herein, the inverter for vehicles 10 is not limited to the examples in the figures. It may have any configuration as long as it functions as an inverter.

In the thus configured inverter for vehicles 10, when high temperature conditions are achieved during operation of the semiconductor chip 2 constituting the power module 1, the solder layer 4, via which the semiconductor chip 2 is positioned on the insulating substrate 3, liquefies or becomes in a solid-liquid coexisting state. This results in relaxation of thermal stress derived from the thermal expansion difference between the above two members. Accordingly, crack generation and the like can be prevented. In addition, the semiconductor chip 2 is stably positioned on the insulating substrate 3 as a result of the connection therebetween with the resin material 5.

One embodiment of the present invention is described above in detail. However, the technical scope of the present invention is not limited thereto. Various changes and modifications to the present invention can be made without departing from the spirit and scope thereof. For instance, silicon grease may be used for connection between a radiator plate and a heat sink. Alternatively, a bonding material such as a solder, an adhesive for good thermal conduction, or the like may be used for such connection.

### INDUSTRIAL APPLICABILITY

In a practical example of the present invention, the power module of the present invention can be applied as a power module for power supply for electric facilities and the like and applied to power supply apparatuses.

1. A power module comprising a semiconductor chip and a substrate on which the semiconductor chip is positioned,
wherein the power module further comprises a solder layer provided between the semiconductor chip and the substrate, the solder layer liquefying at the temperature of heat generation by the semiconductor chip under rated working conditions,
the power module further comprises a resin material that connects the semiconductor chip and the substrate, the resin material deforming to follow the thermal expansion difference between the semiconductor chip and the substrate that is generated upon the heat generation, and
the melting point of the resin material is higher than the melting point of the solder layer.

2. The power module according to claim 1, in which the resin material surrounds at least the circumference of the semiconductor chip.

3. The power module according to claim 1, in which the resin material has a Young's modulus of 1 to 20 GPa.

4. The power module according to claim 1, in which the resin material has a heatproof temperature of 160° C. to 240° C.

5. The power module according to claim 1, in which the resin material is at least one resin selected from the group comprising polyimide resin, epoxy resin, urethane resin, and silicone resin.

6. The power module according to claim 5, in which the resin material has layers comprising plural types of the resins.

7. An inverter for vehicles, which is provided with the power module according to claim 1.
